(19) United States
(12) Patent Application Publication
(10) Pub. No.: US 2025/0224365 A1
(43) Pub. Date: Jul. 10, 2025

(54) SEMICONDUCTOR STRUCTURE INCLUDING MICRO WELLS WITH DIFFERENT HEIGHTS

(71) Applicant: TAIWAN SEMICONDUCTOR MANUFACTURING COMPANY, LTD., Hsinchu (TW)

(72) Inventors: Chuan-Chi Yan, Hsinchu (TW); Chia-Chan Chen, Hsinchu (TW); Cheng-Yen Li, Hsinchu (TW); Yueh-Chuan Lee, Hsinchu (TW)

(73) Assignee: TAIWAN SEMICONDUCTOR MANUFACTURING COMPANY, LTD., Hsinchu (TW)

(21) Appl. No.: 18/404,290

(22) Filed: Jan. 4, 2024

(51) Int. Cl. G01N 27/414; H01L 27/088; H01L 29/06; H01L 29/423; H01L 29/66; H01L 29/78

(52) U.S. Cl. CPC G01N 27/4145; H10D 30/021; H10D 30/60; H10D 30/6891; H10D 62/124; H10D 84/83

(57) ABSTRACT

A semiconductor structure includes a dielectric layer, a first stack and a second stack. The first stack includes a first routing, a first micro well and a first transistor. The first routing formed in the dielectric layer has a first top portion, and a first bottom portion connected to the first transistor. The first micro well extends from an upper surface of the dielectric layer into the first top portion, and has a first height. The second stack includes a second routing, a second micro well, and a second transistor. The second routing formed in the dielectric layer has a second top portion, and a second bottom portion connected to the second transistor. The second micro well extends from the upper surface of the dielectric layer into the second top portion, and has a second height greater than the first height.

### BACKGROUND

Semiconductor structures, including micro wells that are connected to transistors, may serve as biosensors capable of performing different types of analysis, such as DNA sequencing. At each of the micro wells, a target substance is detected, and an electrical signal is transmitted to an analysis system through the transistors for further processing and/or analysis.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor structure in accordance with some embodiments.

FIG. 2 is a fragmentary enlarged view of the semiconductor structure shown in FIG. 1 in accordance with some embodiments.

FIG. 3 is a variation of the semiconductor structure shown in FIG. 2 in accordance with some embodiments.

FIG. 4 is a schematic view of simulation when carrier beads were accommodated in the micro wells of the semiconductor structure shown in FIG. 2 in accordance with some embodiments.

FIG. 5 is a top view of the semiconductor structure in accordance with some embodiments.

FIG. 6 is a flow diagram illustrating a method for manufacturing the semiconductor structure in accordance with some embodiments.

FIGS. 7 to 17 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “topmost,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including micro wells with different heights, and a method for manufacturing the same. The micro wells, which are connected to transistors, are formed with at least two different heights to provide at least two types of accommodation spaces having different accommodation volumes. Such semiconductor structure may serve as a biosensor by which a target substance is detected at each of the micro wells upon introduction of a testing sample into the micro wells, and then an electrical signal is transmitted to an analysis program through the corresponding transistor so as to be analyzed. The micro wells with greater heights and accommodation volumes permit an increased contact between the micro wells and the testing sample because of increase in the contact surface area of the micro wells, thereby enhancing signal intensity level. In addition, the different types of micro wells allow selection and processing of signals received with different intensity levels.

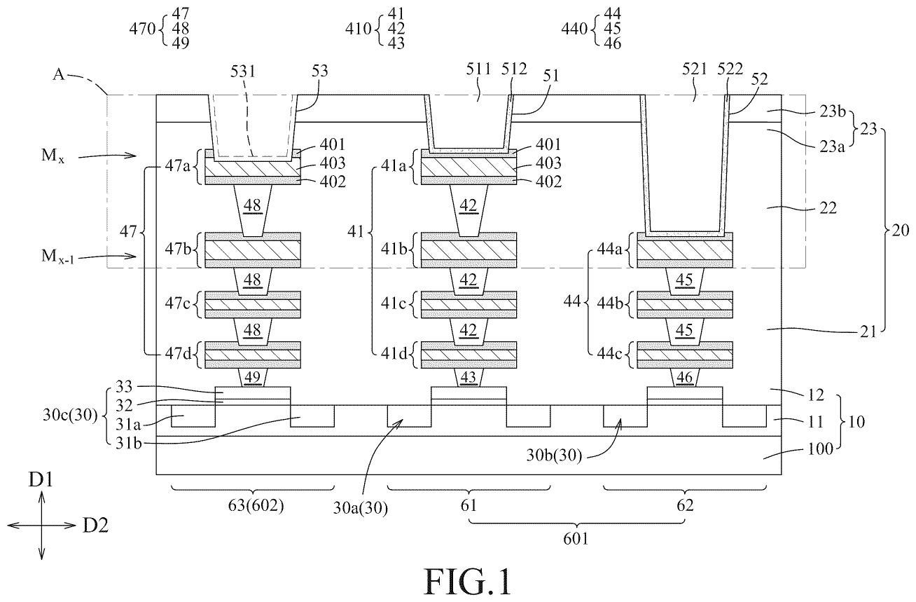

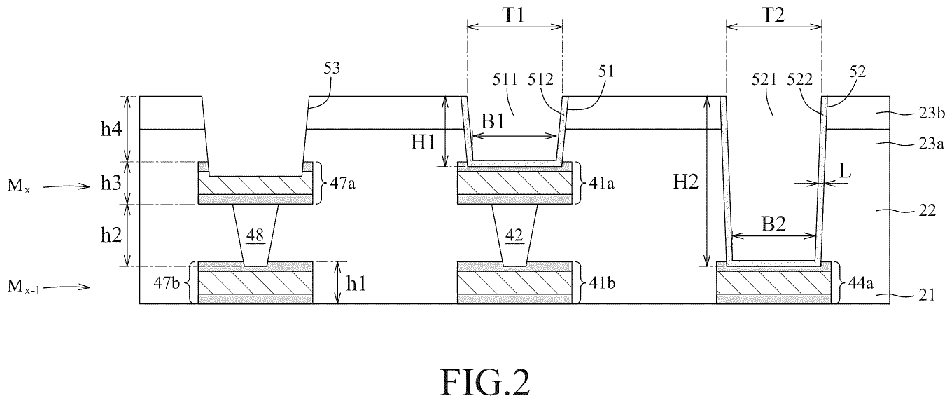

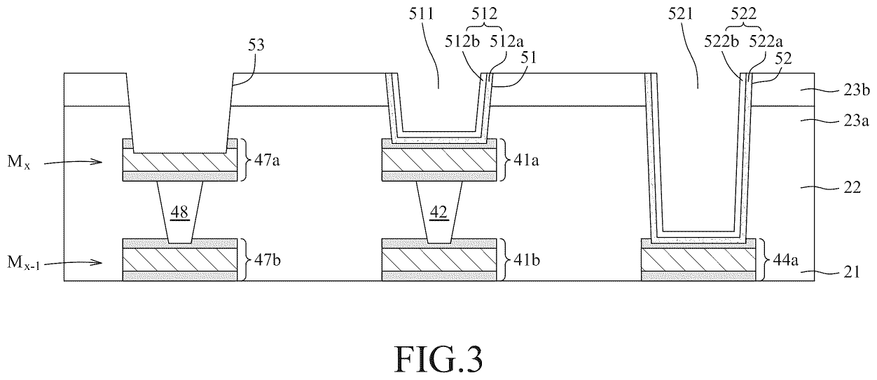

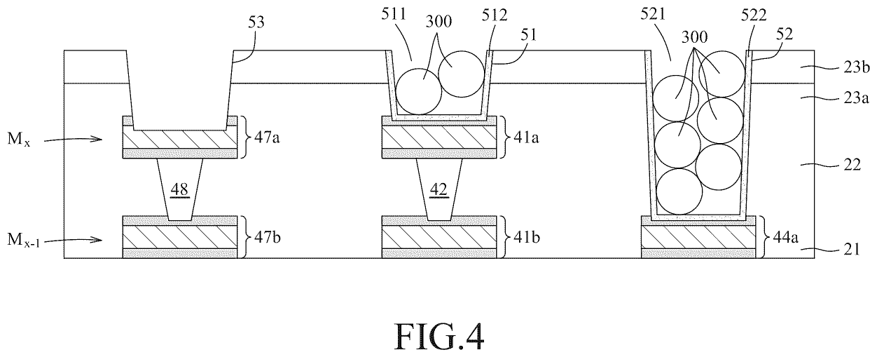

FIG. 1 shows the semiconductor structure of the present disclosure in accordance with some embodiments. FIG. 2 is a fragmentary enlarged view of a region outlined by a dotted line (A) shown in FIG. 1. FIG. 3 is a variation of the structure shown in FIG. 2 in accordance with some embodiments. FIG. 4 is a schematic view simulating the structure shown in FIG. 2 accommodating carrier beads 300 in accordance with some embodiments.

Referring to FIG. 1, along a stacking direction D1, the semiconductor structure includes a base structure 10, and a dielectric layer 20 formed on the base structure 10.

In some embodiments, the dielectric layer 20 may include silicon oxide and/or silicon nitride, so as to form a passivation layer to prevent moisture from entering electronic elements formed therein. Other suitable materials for forming the dielectric layer 20 are within the contemplated scope of disclosure. In accordance with some embodiments, the structure shown in FIG. 1 includes a first dielectric portion 21, a second dielectric portion 22 and a third dielectric portion 23. The first dielectric portion 21, the second dielectric portion 22 and a lower part 23a of the third dielectric portion 23 serve as a silicon oxide portion. An upper part 23b of the third dielectric portion 23 serves as a silicon nitride portion.

In some embodiments, the base structure 10 may include a substrate 11 and a dielectric 12. In some embodiments, the substrate 11 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The material for forming the substrate 11 may be doped with p-type impurities or n-type impurities, or undoped. In addition, the substrate 11 may be a bulk silicon substrate, a silicon-on-insulator (SOI) substrate, or a germanium-on-insulator (GOI) substrate. In some embodiments, the dielectric 12 may be made of silicon oxide. Other suitable materials for forming the substrate 11 and the dielectric 12 are within the contemplated scope of disclosure.

In some embodiments, transistors 30, such as a first transistor 30a, a second transistor 30b, and a third transistor 30c, are formed in the substrate 11 and the dielectric 12. Each of the transistors 30 includes a source 31a and a drain 31b that are spaced apart from each other in a direction D2 transverse to the stacking direction D1 (hereinafter referred to as “transverse direction D2”), and that are formed in formed in and exposed from the substrate 11. In some embodiments, the transverse direction D2 is perpendicular to the stacking direction D1. Each of the transistors 30 further includes a gate electrode 33 formed in the dielectric 12 above and between the source 31a and the drain 31b, and a gate dielectric 32 formed in the dielectric 12 below the gate electrode 33. In some embodiments, each of the source 31a and the drain 31b may be made of silicon, silicon germanium, or other suitable materials, and may be doped with p-type impurities (e.g., boron or other suitable elements), or n-type impurities (e.g., phosphorus, arsenic, other suitable elements, or combinations thereof). The gate dielectric 32 may be made of any suitable high-k or low-k dielectric materials. The gate electrode 33 may be made of one of polysilicon, silicon, metal, metal silicide, and combinations thereof. Other suitable materials for forming the source 31a, the drain 31b, the gate dielectric 32 and the gate electrode 33 are within the contemplated scope of disclosure. Please note that the transistor 30 may be configured as any suitable type of transistor, such as planar transistors, fin-type field-effect transistors (FinFET), nanosheet semiconductor devices (e.g., gate-all-around field-effect transistors (GAAFET), forksheet field-effect transistors, complementary field-effect transistors (CFET), or the likes, or combinations thereof). One may decide the type of the transistor 30 according to practical needs. Other suitable types of the transistors 30 are within the contemplated scope of the present disclosure.

In some embodiments, the base structure 10 may further includes an element 100. The element 100 may be another wafer formed with any suitable active devices such as transistors, capacitors, resistors, decoders, amplifiers, other suitable devices, or combinations thereof. By subjecting a bonding process, or applying an adhesive material, the element 100 may be bonded with the substrate 11 to form the base structure 10. In some other embodiments, the element 100 may also be an adhesive material, which may serve as an adhesive surface of the semiconductor structure so as to be bonded with other elements in further application. Please note that the inclusion of the element 100 is optionally, and may be determined according to practically needs.

Referring to FIG. 1, the semiconductor structure includes a cell region 601 and a logic region 602 that is displaced from the cell region 601 along the transverse direction D2. The cell region 601 includes first stacks 61 (one of which is shown) and second stacks 62 (one of which is shown) that are displaced from each other. The logic region 602 includes pad stacks 63 (one of which is shown) that are displaced from the first stacks 61 and the second stacks 62. The first stacks 61, the second stacks 62 and the pad stacks 63 are respectively described in terms of one first stack 61, one second stack 62, and one pad stack 63 hereinafter.

The first stack 61 includes a first routing 410, a first micro well 51, and the first transistor 30a, and may function as a first bioFET. The first routing 410 connected to the gate electrode 33 of the first transistor 30a may serve as a floating gate for the first bioFET. The first routing 410 is formed in the dielectric layer 20, and has a first top portion 41a and a first bottom portion 43 opposite to the first top portion 41a in the stacking direction D1. The first micro well 51 extends downwardly from the upper surface of the dielectric layer 20 into the first top portion 41a. The first transistor 30a is connected to the first bottom portion 43. In some embodiments, the first micro well 51 has a first height H1 (see FIG. 2). In some embodiments, the first micro well 51 has a first accommodation volume.

The second stack 62 includes a second routing 440, a second micro well 52, and the second transistor 30b, and may function as a second bioFET. The second routing 440 connected to the gate electrode 33 of the second transistor 30b may serve as a floating gate for the second bioFET. The second routing 440 is formed in the dielectric layer 20, and has a second top portion 44a and a second bottom portion 46 opposite to the second top portion 44a in the stacking direction D1. The second micro well 52 extends downwardly from the upper surface of the dielectric layer 20 into the second top portion 44a. The second transistor 30b is connected to the second bottom portion 46. In some embodiments, as shown in FIG. 2, the second micro well 52 has a second height H2 greater than the first height H1. In some embodiments, the second micro well 52 has a second accommodation volume that is larger than the first accommodation volume.

In some embodiments, the first routing 410 includes a plurality of first metal layers 41, first vias 42, and a first gate contact 43. The first metal layers 41, the first vias 42 and the first gate contact 43 are configured to interconnect a first sensing layer 512 in the first micro well 51 with the first transistor 30a. In this case, the topmost first metal layer 41a serves as the first top portion, and the first gate contact 43 serves as the first bottom portion.

The first metal layers 41 are formed in the dielectric layer 20 and are connected to each other through the first vias 42 along the stacking direction D1. In some embodiments, each of the first metal layers 41 includes an upper film 401, a lower film 402, and a main body 403 sandwiched between the upper film 401 and the lower film 402. Each of the upper film 401 and the lower film 402 includes a material different from a material of the main body 403. In some embodiments, examples of the material for making the upper film 401 and the lower film 402 include titanium and titanium nitride, but are not limited thereto. In some embodiments, examples of the material for making the main body 403 include aluminum copper, aluminum, copper, tungsten, but are not limited thereto. In some embodiments, the first vias 42 are made of tungsten, or copper, or the like, or combinations thereof. Other suitable materials for making the upper film 401, the lower film 402, the main body 403, and the first vias 42 are within the contemplated scope of disclosure. In accordance with some embodiments, each of the upper film 401 and the lower film 402 is made of titanium nitride, while the main body 403 is made of aluminum copper. In some embodiments, the first vias 42 are made of tungsten.

A number of the first metal layers 41 may be determined according to practical needs. In the structure shown in FIG. 1, there are four first metal layers arranged along the stacking direction D1 and are respectively denoted as 41d, 41c, 41b, and 41a. In other embodiments, there may be more, or fewer the first metal layers 41.

In some embodiments, each of the first vias 42 extends from a lower surface of an upper adjacent one of the first metal layers 41 into the upper film 401 of a lower adjacent one of the first metal layers 41 to stop short of the main body 403 of the lower adjacent one of the first metal layers 41.

The first transistor 30a is connected to the bottommost first metal layer 41d through the first gate contact 43. The first gate contact 43 may be made of a material similar to that of the first vias 42.

In some embodiments, the number of the first transistor 30a in the first stack 61 is one. The number of the first metal layers 41 depends on a routing required for the first transistor 30a. The greater number of the first metal layers 41 allows greater number of the first transistors 30a for performing more complex processing and/or analysis. In some other embodiments, the first stack 61 may include multiple first transistors 30a (one of which is shown in FIG. 1) connected to one or more of the first micro wells 51 through the first routing 410.

The first micro well 51 extends downwardly from an upper surface of the dielectric layer 20 into the topmost first metal layer 41a. For instance, in some embodiments, the first micro well 51 extends into the upper film 401 of the topmost first metal layer 41a to stop short of the main body 403 of the topmost first metal layer 41a. As shown in FIGS. 1 and 2, in accordance with some embodiments, the first micro well 51 is bordered by the silicon oxide portion 23b, the silicon nitride portion 23a and the remaining upper film 401 of the topmost first metal layer 41a, so as to protect any elements underneath from entry of moisture.

The first sensing layer 512 is disposed on an inner surface of the first micro well 51 so as to define a first accommodation space 511 of the first micro well 51. The first accommodation space 511 has the first accommodation volume. In some embodiments, the first sensing layer 512 is conformally formed along the inner surface, i.e., a sidewall and a bottom portion of the inner surface of the first micro well 51.

The first sensing layer 512 is formed according to practical needs, by varying thickness L (see FIG. 2), and/or material, and/or composition of the first sensing layer 512. In some embodiments, the first sensing layer 512 may have a single-layer film structure (see FIGS. 1 and 2). In some embodiments, the first sensing layer 512 may include an electrically conductive material, a dielectric material, a polymeric material, or combinations thereof. In other embodiments, the first sensing layer 512 may have a multi-layered structure by including films 512a, 512b that are made of different materials (see FIG. 3). Each of the films 512a, 512b may include an electrically conductive material, a dielectric material, a polymeric material, or combinations thereof.

In some embodiments, the second routing 440 includes at least one second metal layer 44 and a second gate contact 46. The at least one second metal layer 44 serves as the second top portion, and the second gate contact 46 serves as the second bottom portion. In some embodiments, as shown in FIG. 1, the at least one second metal layer 44 includes a plurality of second metal layers 44, and the second routing 440 further includes second vias 45. The second metal layers 44 are connected to each other through the second vias 45, and in this case, the topmost second metal layer 44a serves as the second top portion. The second metal layers 44, the second vias 45 and the second gate contact 46 are configured to interconnect a second sensing layer 522 in the second micro well 52 with the second transistor 30b.

The second metal layers 44 are formed in the dielectric layer 20, and are connected to each other through second vias 45 along the stacking direction D1. The structure, configuration and materials of the second metal layers 44 and the second vias 45 are respectively similar to that of the first metal layers 41 and the first vias 42, and thus are not repeated for the sake of brevity.

The second transistor 30b is connected to the bottommost second metal layer 44c through the second gate contact 46. The second gate contact 46 may be made of a material similar to that of the second vias 45.

In some embodiments, the number of the second transistor 30b in the second stack 62 is one. The number of the second metal layers 44 depends on a routing required for the second transistor 30b. The greater number of the second metal layers 44 allows greater number of the second transistors 30b for performing more complex processing and/or analysis. In other embodiments, the second stack 62 may include multiple second transistors 30b (one of which is shown in FIG. 1) connected to one or more of the second micro wells 52 through the second routing 440.

The second micro well 52 extends downwardly from an upper surface of the dielectric layer 20 into the topmost second metal layer 44a. The second micro well 52 is similar to the first micro well 51 in many aspects. For instance, the second micro well 52 may also extend into the upper film 401 of the topmost second metal layer 44a to stop short of the main body 403 of the topmost second metal layer 44a. The second micro well 52 may be bordered by the silicon oxide portion 23b, the silicon nitride portion 23a, and the remaining upper film 401 of the topmost second metal layer 44a.

The second sensing layer 522 is disposed on an inner surface of the second micro well 52 so as to define a second accommodation space 521 of the second micro well 52. The second accommodation space 521 has the second accommodation volume. In some embodiments, the second sensing layer 522 is conformally formed along the inner surface, i.e., a sidewall and a bottom portion of the inner surface of the second micro well 52.

The configuration, structure and material(s) of the second sensing layer 522 may be similar to that of the first sensing layer 512 of the first micro well 51, and thus are not repeated for the sake of brevity. For instance, in some embodiments, referring to FIG. 3, when each of the first and second sensing layers 512, 522 has a multi-layered structure, the material of the film 512a of the first sensing layer 512 may be similar to the material of a film 522a of the second sensing layer 522, while the material of the film 512b of the first sensing layer 512 may be similar to a film 522b of the second sensing layer 522. In other embodiments, the first and the second sensing layers 512, 522 may also have different structure and/or materials depending on practical needs.

It is noted that the first stack 61 and the second stack 62 differs in the number of the first metal layers 41 and the number of the second metal layers 22. For instance, as shown in FIG. 1, along the stacking direction D1, in the first stack 61, there are four the first metal layers 41 respectively denoted as 41d, 41c, 41b, and 41a, while in the second stack 62, there are three second metal layers 44 respectively denoted as 44c, 44b, and 44a. That is, the second metal layers 44 have one metal layer less than the first metal layers 41. The topmost second metal layer 44a is at a level lower than that of the topmost first metal layer 41a. The topmost second metal layer 44a is at a level same as that of the first metal layer 41b which is next to and below the topmost first metal layer 41a.

Referring to FIG. 2, a second difference between the first stack 61 and the second stack 62 is that, the second height H2 of the second micro well 52 is greater than the first height H1 of the first micro well 51. The first and second micro wells 51, 52 both extend from the upper surface of the dielectric layer 20, and respectively into the topmost first metal layer 41a (which is located at a higher level) and the topmost second metal layer 44a (which is located at a lower level). As such, the second micro well 52 is formed with the second height H2 that is greater than the first height H1 of the first micro well 51. The second height H2 is approximately a sum of a height h2 of the topmost first via 42, a height h3 of the topmost first metal layer 41a, and a height h4 of the third dielectric portion 23 of the dielectric layer 20 located above the topmost first metal layer 41a, i.e., H2=h2+h3+h4. It is clear that in the exemplary example shown in FIGS. 1 and 2, the second micro well 52 is formed to extend from the upper surface of the dielectric layer 20 through the third dielectric portion 23, through the second dielectric portion 22 at the topmost interconnect level Mₓ and into the topmost second metal layer 44a at the lower interconnect level Mₓ₋₁. On the other hand, the first micro well 51 is formed to extend from the upper surface of the dielectric layer 20 through the third dielectric portion 23 and into the topmost first metal layer 41a at the topmost interconnect level Mₓ. Such structure allows the second micro well 52 to have the second accommodation volume that is larger than the first accommodation volume of the first micro well 51, and thus the second micro well 52 is capable of accommodating more of the carrier beads 300 in comparison with the first micro well 51 (see FIG. 4). As such, a contact surface area between the carrier beads 300 accommodated in the second micro well 52 and the second sensing layer 522 of the second micro well 52 is greater than a contact surface area between the carrier beads 300 accommodated in the first micro well 51 and the first sensing layer 512 of the first micro well 51, which is favorable to enhance signal intensity level received from the second micro well 52, and thus enhances the accuracy of analysis performed based on the enhanced signal intensity level.

FIG. 4 is a schematic view illustrating operation of the semiconductor structure that serves as a biosensor. In accordance with some embodiments, a packaging element (not shown) is provided for packaging the semiconductor structure shown in FIG. 1, so as to create a passage (not shown) between the semiconductor structure and the packaging element, and the passage is in spatial communication with the first and second micro wells 51, 52. The packaging element is also formed with an inlet (not shown, upstream of the passage) and an outlet (not shown, downstream of the passage) to allow material(s) to flow through the semiconductor structure. For instance, the inlet permits entry of an analyte and/or the carrier beads 300 which are directed to the first and second micro wells 51, 52 through the passage, and which are then directed to the outlet through the passage. As the analyte and/or the carrier beads 300 reach the first and second micro wells 51, 52, the first and second sensing layers 512, 522 are each in contact with a target substance (may be a substance within the analyte and/or the carrier beads 300, or may be a substance derived upon interaction of materials in the analyte and/or the carrier beads 300). The target substance alters a voltage of the gate electrode 33 of each of the first and second transistors 30a, 30b, and thus altering an amount of a current between the source 31a and the drain 31b of each of the first and second transistors 30a, 30b. The change in the current serves as an electrical signal that is transmitted for further processing and/or analysis. The mechanism enabling the target substance to trigger voltage change of the gate electrode 33 of each of first and second transistors 30a, 30b may vary case by case, for example, based on chemical, optical, or biological properties of the target substance. For instance, in some embodiments, the first and second sensing layers 512, 522 are designed to trigger change of gate voltage by combining with specific molecules. In other embodiments, change in amount of ions and/or charges present in the analyte and/or the carrier beads 300 in the first and second micro wells 51, 52 may trigger the voltage change. In some other embodiments, the first and second sensing layers 512, 522 may be designed to conduct electricity under specific circumstances. In yet other embodiments, different segments of DNA strands trigger different signals. Other suitable mechanisms/and or principles for altering voltage of the gate electrodes 33 of the first and second transistors 30a, 30b are within the contemplated scope of the present disclosure.

In order to further increase the contact surface area between a testing sample (e.g., the analyte and/or the carrier beads 300) and each of the first and second sensing layers 512, 522 so that the signal detected has greater intensity level, it is desirable to form the first and second micro wells 51, 52 with the first and second accommodation spaces 511, 521 that precisely accommodate the analyte and/or the carrier beads 300. When the first and second accommodation volumes are too large, the testing sample could not be in sufficient contact with the first and second sensing layers 512, 522 (e.g., not all of the carrier beads 300 could not be in contact with the first and second sensing layers 512, 522), which adversely affect signal detection. When the first and second accommodation volumes are too small, the first and second micro wells 51, 52 could only accommodate a small quantity of the analyte and/or the carrier beads 300, which results in detection of a weak signal. As such, the first and second micro wells 51, 52 are to be well designed. For instance, shapes, critical dimensions (e.g., top width T1, bottom width B1 for the first micro well 51, or top width T2, bottom width B2 for the second micro well 52, see FIG. 2), slopes of sidewalls, or other suitable parameters, of the first and second micro wells 51, 52, but are not limited thereto, may be varied by adjusting working conditions of forming the first micro well 51 and the second micro well 52.

The semiconductor structure allows detection of different signals (e.g., signals with different intensity levels, but are not limited thereto) from the first and second micro wells 51, 52 having different heights and different volumes. Users may freely select only one signal detected from one of the first and second micro wells 51, 52, or utilize the signals detected from both the first and second micro wells 51, 52, to facilitate processing and/or analysis of the signal(s).

Signals detected from the cell region 601 (e.g., from the first and second micro wells 51, 52) are transmitted, through the pad stack 63 located at the logic region 602, to an analysis system (not shown) for further processing and/or analysis. Referring back to FIGS. 1 and 2, the pad stack 63 is similar to the first stack 61. The pad stack 63 includes a third routing 470, a pad opening 53, and the third transistor 30c. The third routing 470 is formed in the dielectric layer 20, and has a third top portion 47a and a third bottom portion 49 opposite to the third top portion 47a in the stacking direction D1. The pad opening 53 extends downwardly from the upper surface of the dielectric layer 20 into the third top portion 47a. The third transistor 30c is connected to the third bottom portion 49.

In some embodiments, the third routing 470 includes at least one third metal layer 47 and a third gate contact 49. The at least one third metal layer 47 serves as the third top portion, and the third gate contact 49 serves as the third bottom portion. In some embodiments, as shown in FIG. 1, the at least one third metal layer 47 includes a plurality of third metal layers 47, and the third routing 470 further includes third vias 48. The third metal layers 47 are connected to each other through the third vias 48, and in this case, the topmost third metal layer 47a serves as the third top portion. The third metal layers 47, the third vias 48 and the third gate contact 49 are configured to interconnect a pad 531 (which may be a connection portion of any other element that is configured to be connected to the semiconductor structure according to application of the semiconductor structure and/or practical needs. For instance, the pad 531 may be the connection portion of the analysis system that receives, and processes and/or analyzes signal(s) from the semiconductor structure, but is not limited thereto, see FIG. 1) formed in the pad opening 53 with the third transistor 30c. The pad opening 53 serves as a contact site between the semiconductor structure and the analysis system, or any other suitable devices that are designed to be electrically connected with the cell region 601, or with the semiconductor structure.

The third metal layers 47 are similar to the first and second metal layers 41, 44, the third vias 48 are similar to the first and second vias 42, 45, and the third gate contact 49 is similar to the first and second gate contacts 43, 46, in terms of structure, configuration, and materials, and thus details thereof are not repeated for the sake of brevity. For instance, as shown in FIG. 1, in some embodiments, a number of the third metal layers 47 is equal to a number of the first metal layers 41. That is, the topmost third metal layer 47a is located at a level same as that of the topmost first metal layer 41a (i.e., at the topmost interconnect level Mₓ), and is located at a level higher than the topmost second metal layer 44a (which is located at the interconnect level Mₓ₋₁). In other embodiments, the number of the third metal layers 47 may be equal to a number of the second metal layers 44. In yet other embodiments, the number of the third metal layers 47 may be different from the number of the first metal layers 41, or the number of the second metal layers 44.

In some embodiments, as shown in FIG. 1, the pad opening 53 is formed to extend from the upper surface of the dielectric layer 20 through the third dielectric portion 23 and into the topmost third metal layer 47a at the topmost interconnect level Mₓ. The difference between the pad opening 53 of the pad stack 63, and the first micro well 51 of the first stack 61, or the second micro well 52 of the second stack 62, is that the pad opening 53 may be free from any sensing layers like the first and second sensing layers 512, 521 since the pad opening 53 is configured for forming the pad 531 (for electrical connection) but not for signal detection. In addition, in some embodiments, unlike the first and second micro wells 51, 52, the pad opening 53 penetrates through the upper film 401 of the topmost third metal layer 47a to stop at the main body 403 of the topmost third metal layer 47a.

In some embodiments, the number of the third transistor 30c in the pad stack 63 is one. In other embodiments, the pad stack 63 may include multiple third transistors 30c (one of which is shown in FIG. 1) connected to the pad(s) in one or more of the pad openings 53 through the third routing 470.

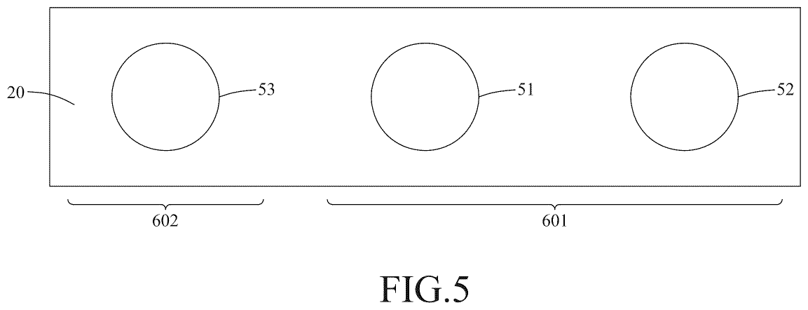

FIG. 5 is a top schematic view of the semiconductor structure in accordance with some embodiments for illustrating profiles of the first micro well 51, the second micro well 52, and the pad opening 53, in which the first and second sensing layers 512, 522 shown in FIG. 1 are not shown. In some embodiments, each of the first micro well 51, the second micro well 52, and the pad opening 53 has a circular shape when being viewed along the stacking direction D1, whilst in other embodiments, each of the first micro well 51, the second micro well 52, and the pad opening 53 may have any suitable shapes (e.g., a polygon shape). The first micro well 51, the second micro well 52, and the pad opening 53 may have the same or different top view profiles.

In some other embodiments, the semiconductor structure may further include other stacks formed with other micro wells (not shown) each of which has a configuration similar to the first and second micro wells, 51, 52, and each of which has a height different from the first height H1 of the first micro well 51 and the second height H2 of the second micro well 52.

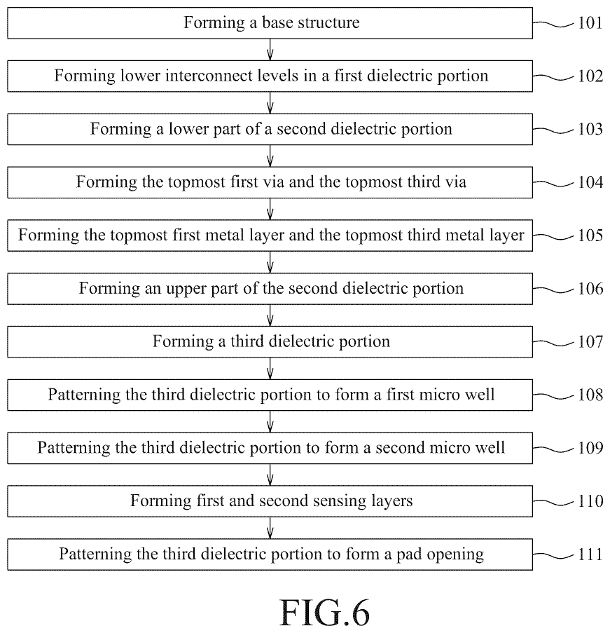

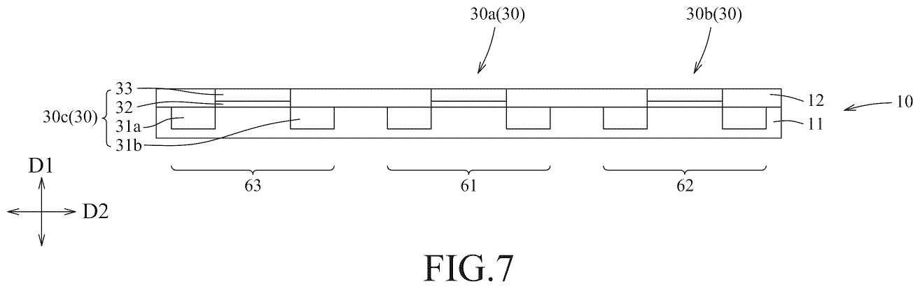

FIG. 6 is a flow diagram illustrating a method for manufacturing the semiconductor structure shown in FIG. 1 in accordance with some embodiments. FIGS. 7 to 17 illustrate schematic views of intermediate stages of the method in accordance with some embodiments. Some repeating structures are omitted in FIGS. 7 to 17 for the sake of brevity. Additional steps can be provided before, after or during the method, and some of the steps described herein may be replaced by other steps or be eliminated.

Referring to FIG. 6 and the example illustrated in FIG. 7, the method begins at step 101, where the base structure 10 (the element 100 shown in FIG. 1 is omitted) including the transistors 30 is formed.

As aforementioned, for each of the transistors 30, the source 31a and the drain 31b are formed in the substrate 11, while the gate dielectric 32 and the gate electrode 33 are formed in the dielectric 12. Depending on the type of transistor to be adopted in the semiconductor structure, fabrication process of the transistors 30 may be different and is not described in this disclosure. One may adopt any suitable techniques known in the art to prepare the transistors 30.

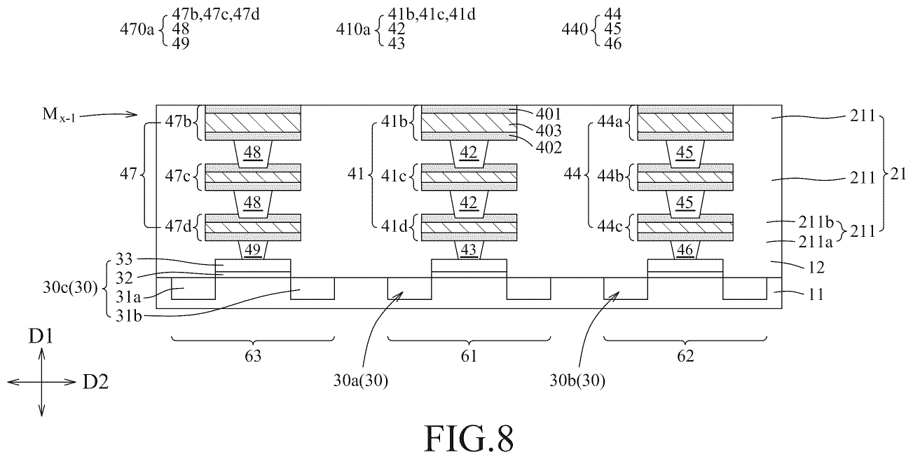

Referring to FIG. 6 and the example illustrated in FIG. 8, the method proceeds to step 102, where lower interconnect levels, (interconnect levels other the topmost interconnect level Mₓ), are formed over the base structure 10. In other word, in step 102, a lower part 410a of the first routing 410 (see FIGS. 1 and 8), the second routing 440, and a lower part 470a of the third routing 470 (see FIGS. 1 and 8) are formed in the first dielectric portion 21.

In some embodiments, metal layers located at the same interconnect level may be formed in the same process, and the vias (or the gate contacts) at the same level may be formed in the same process. For instance, the first, second and third gate contacts 43, 46, 49 are formed in the same process, the vias 42, 45, 48 at the same level are formed in the same process, and the metal layers 41, 44, 47 are formed in the same process. In some embodiments, a number of the lower interconnect levels is three. At the bottommost interconnect level, after formation of the first, second and third gate contacts 43, 46, 49, the bottommost first metal layer 41d, the bottommost second metal layer 44c and the bottommost third metal layer 47d are formed in the bottommost one of sections 211 of the first dielectric portion 21. At the intermediate interconnect level, after formation of the first, second and third vias 42, 45, 48 immediately above the elements 41d, 44c, 47d, the first metal layer 41c, the second metal layer 44b and the third metal layer 47c are formed in the intermediate one of the sections 211. At the interconnect level Mₓ₋₁, after formation of the first, second and third vias 42, 45, 48 immediately above the elements 41c, 44b, 47c, the first metal layer 41b, the topmost second metal layer 44a and the third metal layer 47b are formed over the in the topmost one of the sections 211.

Formation of each of the aforementioned lower interconnect levels includes six sub-steps. In the first sub-step, a lower part 211a of the corresponding section 211 is deposited. In the second sub-step, the lower part 211a is patterned to form openings penetrating the lower part 211a. In the third sub-step, conductive portions (serving as the first, second or third gate contacts or vias 43, 46, 49, 42, 45 and 48) are respectively formed in the openings. In the fourth sub-step, three material layers for respectively serving as the lower film 402, the main body 403 and the upper film 401 are deposited over the lower part 211a. In the fifth sub-step, the three material layers are patterned to form the first, second and third metal layers 41, 44, 47. In the sixth sub-step, an upper part 211b of the corresponding section 211 is formed over the lower part 211a to expose the first, second and third metal layers 41, 44, 47. Formation of the upper part 211b may include depositing a suitable material to cover the first, second and third metal layers 41, 44, 47, followed by a planarization process to expose the first, second and third metal layers 41, 44, 47. In this step, the deposition processes may include chemical vapour deposition (CVD), atomic layer deposition process (ALD), physical vapour deposition (PVD), combinations thereof, or other suitable processes; the patterning processes may include photolithography processes, etching processes (e.g., wet etching, dry etching), or other suitable processes; and the planarization processes may include chemical mechanical polishing (CMP) processes or other suitable processes.

In the second sub-step of step 102, the openings that are configured to accommodate the first, second, and third vias 42, 45, 48 are formed to extend into upper film 401 of a corresponding metal layer underneath.

By completing step 102, all the second metal layers 44 of the second stack 62 are thereby obtained.

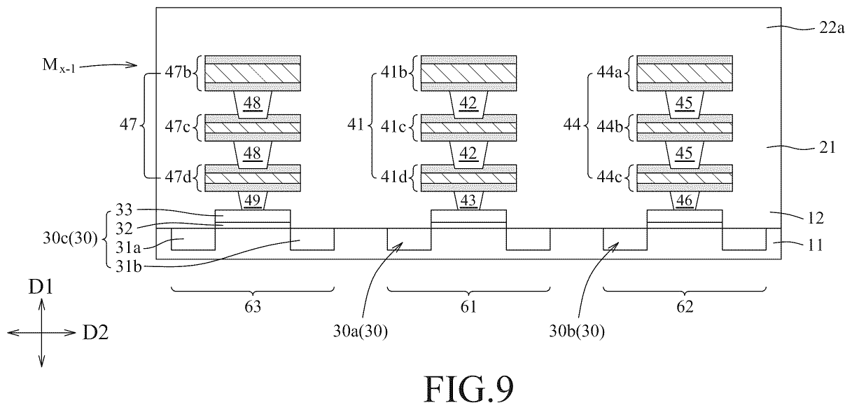

Referring to FIG. 6 and the example illustrated in FIG. 9, the method proceeds to step 103, where a lower part 22a of the second dielectric portion 22 is formed over the interconnect level Mₓ₋₁. The step 103 may be performed using a suitable deposition process. The deposition processes may include chemical vapour deposition (CVD), atomic layer deposition process (ALD), physical vapour deposition (PVD), combinations thereof, or other suitable processes.

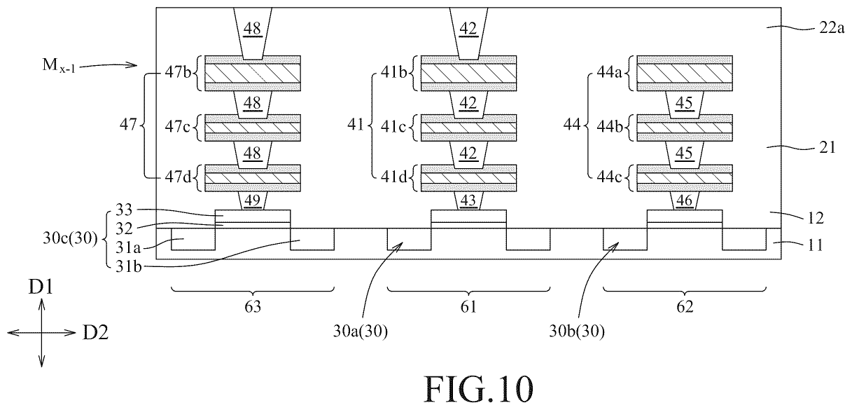

Referring to FIG. 6 and the example illustrated in FIG. 10, the method proceeds to step 104, where the topmost first via 42 and the topmost third via 48 are respectively formed on the first metal layer 41b and the third metal layer 47b.

The step 104 may be performed by patterning the lower part 22a to form holes which respectively partially expose the first metal layer 41b and the third metal layer 47b, filling the holes with a metal material (for forming the topmost first via 42 and the topmost third via 48) using suitable deposition processes, and removing an excess of the metal material using a planarization process. In this step, the deposition processes may include chemical vapour deposition (CVD), atomic layer deposition process (ALD), physical vapour deposition (PVD), combinations thereof, or other suitable processes; the patterning processes may include photolithography processes, etching processes (e.g., wet etching, dry etching), or other suitable processes; and the planarization processes may include chemical mechanical polishing (CMP) processes or other suitable processes.

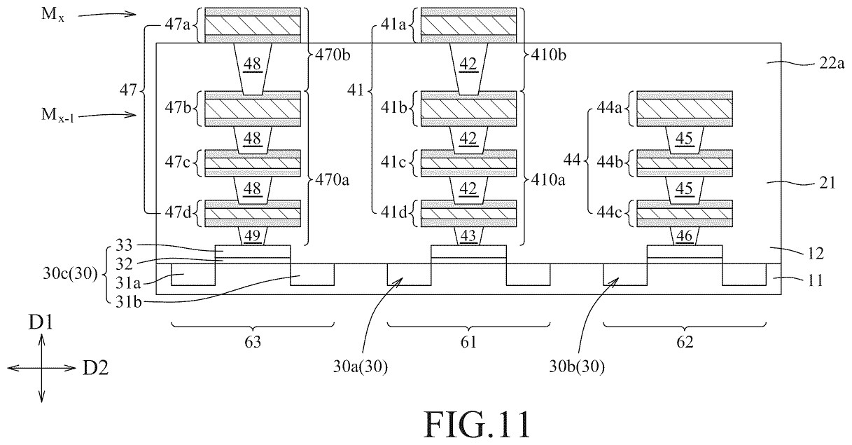

Referring to FIG. 6 and the example illustrated in FIG. 11, the method proceeds to step 105, where the topmost first metal layer 41a and the topmost third metal layer 47a are formed on the lower part 22a to respectively cover the topmost first via 42 and the topmost third via 48. Step 105 may include depositing three material layers for forming the lower film 402, the main body 403 and the upper film 401 of the metal layers 41a, 47a on the lower part 22a, followed by patterning so as to obtain the metal layers 41a, 47a. In this step, the deposition processes may include chemical vapour deposition (CVD), atomic layer deposition process (ALD), physical vapour deposition (PVD), combinations thereof, or other suitable processes; and the patterning processes may include photolithography processes, etching processes (e.g., wet etching, dry etching), or other suitable processes.

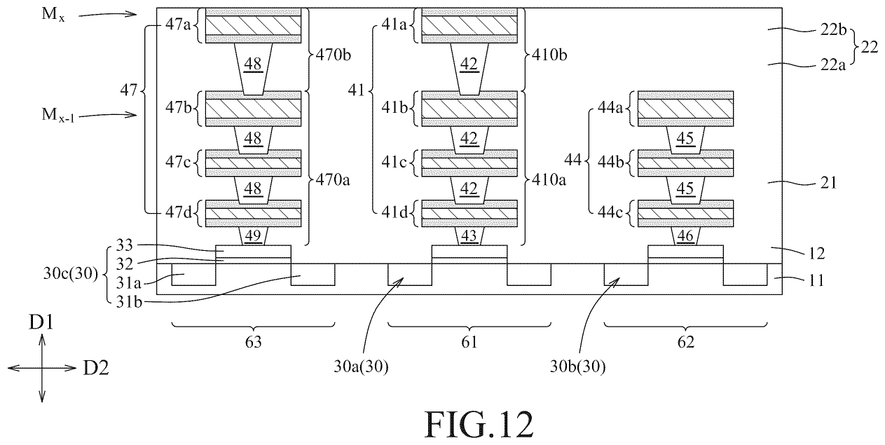

Referring to FIG. 6 and the example illustrated in FIG. 12, the method proceeds to step 106, where an upper part 22b of the second dielectric portion 22 is formed around the metal layers 41a, 47a. The upper part 22b may be formed by depositing a suitable material over the lower part 22a to cover the metal layers 41a, 47a, followed by a suitable planarization process to expose the metal layers 41a, 47a. In this step, the deposition processes may include chemical vapour deposition (CVD), atomic layer deposition process (ALD), physical vapour deposition (PVD), combinations thereof, or other suitable processes; and the planarization processes may include chemical mechanical polishing (CMP) processes or other suitable processes. After step 106, an upper part 410b of the first routing 410 (see FIGS. 1 and 12) and an upper part 470b of the third routing 470 (see FIGS. 1 and 12) are formed in the second dielectric portion 22.

Steps 103 to 106 cooperatively form the topmost interconnect level Mₓ, which includes the topmost first metal layer 41a, the topmost third metal layer 47a, the topmost one of the first via 42 and the topmost one of the third via 48. By completing step 106, all the first metal layers 41 of the first stack 61 and all the third metal layers 47 of the third stack 63 are obtained. It is noted that at the topmost interconnect level Mₓ, metal layers are present at the first stack 61 and the third stack 63, while no metal layer is present at the second stack 62.

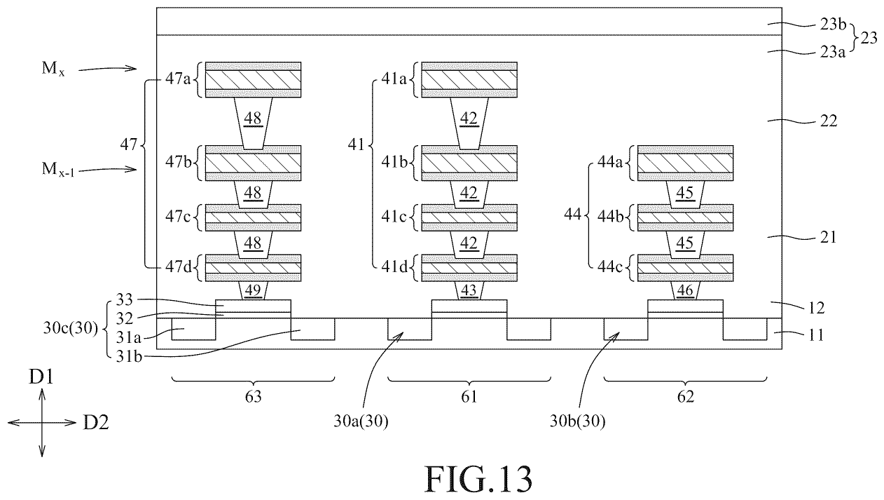

Referring to FIG. 6 and the example illustrated in FIG. 13, the method proceeds to step 107, where the third dielectric portion 23 including the lower part 23a (e.g., the silicon oxide portion) and the upper part 23b (e.g., the silicon nitride portion) are sequentially deposited over the topmost interconnect level Mₓ. The deposition processes may include chemical vapour deposition (CVD), atomic layer deposition process (ALD), physical vapour deposition (PVD), combinations thereof, or other suitable processes;

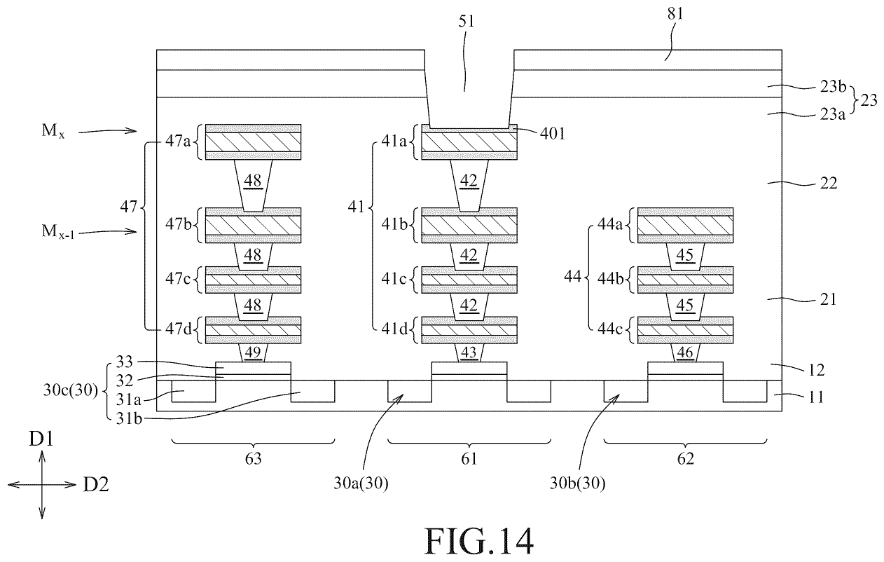

Referring to FIG. 6 and the example illustrated in FIG. 14, the method proceeds to step 108, where the third dielectric portion 23 is patterned to form the first micro well 51 using a first patterning mask 81.

The step 108 may include four sub-steps. In the first sub-step, a photoresist material layer (not shown) is formed over the third dielectric portion 23. In the second sub-step, the photoresist material layer is patterned to form the first patterning mask 81 with an opening in position corresponding to the first micro well 51 to be formed thereafter. In the third sub-step, the third dielectric portion 23 and the upper film 401 of the first metal layer 41a are patterned through the first patterning mask 81 to form the first micro well 51 and exposing a remaining portion of the upper film 401 of the first metal layer 41a. In the fourth sub-step, the first patterning mask 81 is removed. The patterning processes may include etching processes (e.g., wet etching, dry etching) and/or other suitable processes.

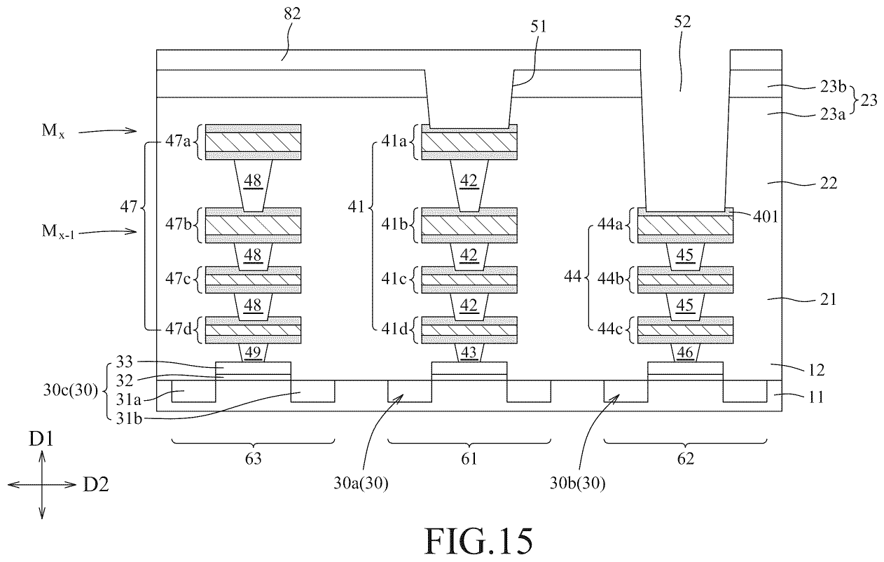

Referring to FIG. 6 and the example illustrated in FIG. 15, the method proceeds to step 109, where the third dielectric portion 23 is patterned to form the second micro well 52 using a second patterning mask 82.

The step 109 may include four sub-steps of. In the first sub-step, a photoresist material layer (not shown) is formed over the third dielectric portion 23 and filling the first micro well 51. In the second sub-step, the photoresist material layer is patterned to form the second patterning mask 82 with an opening in position corresponding to the second micro well 52 to be formed thereafter. In the third sub-step, the third dielectric portion 23, the second dielectric portion 22 and the upper film 401 of the second metal layer 44a are patterned through the second patterning mask 82 to form the second micro well 52 and exposing a remaining portion of the upper film 401 of the second metal layer 44a. In the fourth sub-step, the second patterning mask 82 is removed. The patterning processes may include etching processes (e.g., wet etching, dry etching) and/or other suitable processes.

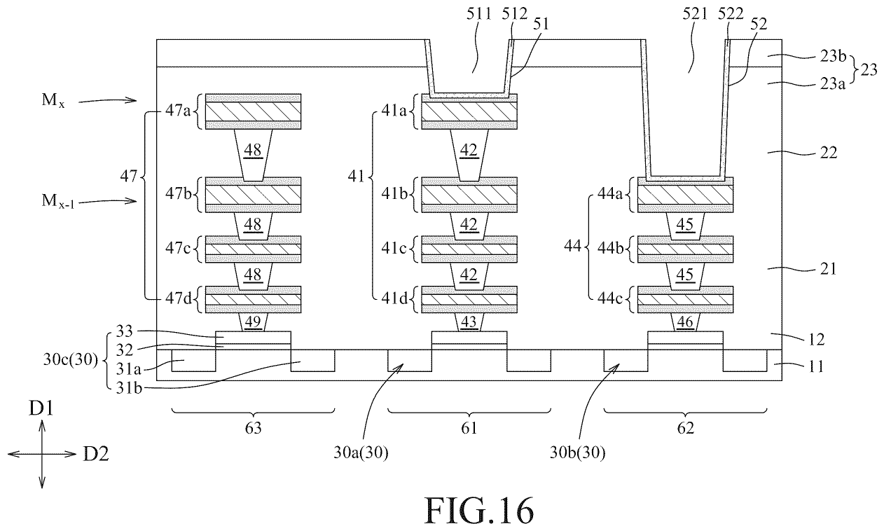

Referring to FIG. 6 and the example illustrated in FIG. 16, the method proceeds to step 110, where the first sensing layer 512 and the second sensing layer 522 are respectively formed on an inner surface of the first micro well 51 and on an inner surface of the second micro well 52.

In some embodiments, the step 110 includes two sub-steps. In the first sub-step, a sensing material layer (not shown, for forming the first and second sensing layers 512, 522) is deposited over the third dielectric portion 23 and along inner surfaces of the first and second micro wells 51, 52. In the second sub-step, a planarization process, such as chemical mechanical polishing (CMP) processes or other suitable processes is performed to remove an excess amount of the sensing material layer, thereby exposing the third dielectric portion 23 and obtaining the first and second sensing layers 512, 522.

In some embodiments, the first sub-step of step 110 is performed using an atomic layered deposition process, but is not limited thereto.

In some embodiments, when the first and second sensing layers 512, 522 are made of the same materials, may be formed using the same process. In other embodiments, when the first and second sensing layers 512, 522 are made of different materials may be also be formed using different processes.

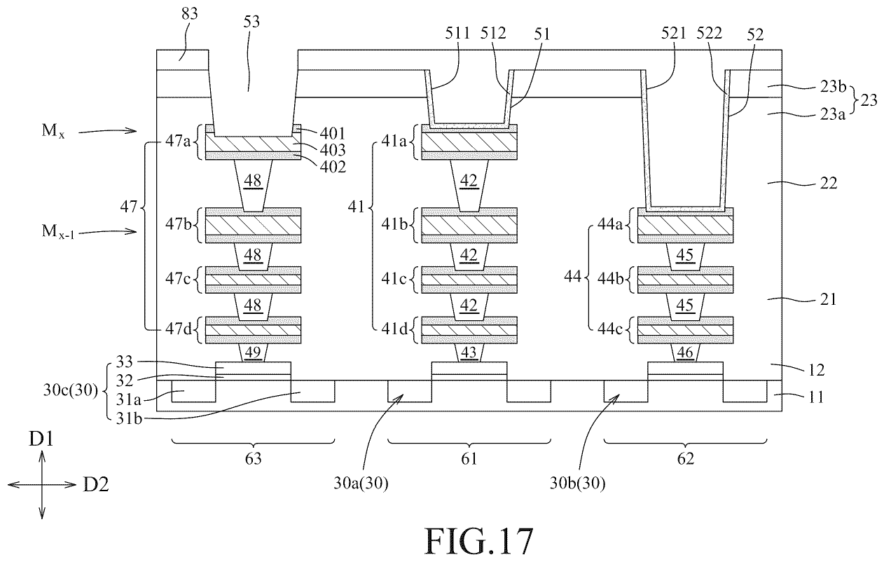

Referring to FIG. 6 and the example illustrated in FIG. 17, the method proceeds to step 111, where the third dielectric portion 23 is patterned to form the pad opening 53 using a third patterning mask 83.

The step 111 may include four sub-steps. In the first sub-step, a photoresist material layer (not shown) is formed over the third dielectric portion 23 and filling the first and second accommodation spaces 511, 521 of the first and second micro wells 51, 52. In the second sub-step, the photoresist material layer is patterned to form the third patterning mask 83 with an opening in position corresponding to the pad opening 53 to be formed thereafter. In the third sub-step, the third dielectric portion 23 and the upper film 401 of the topmost third metal layer 47a are patterned through the third patterning mask 83 to form the pad opening 53 and exposing the main body 403 of the topmost third metal layer 47a. In the fourth sub-step, the third patterning mask 83 is removed. The patterning processes may include etching processes (e.g., wet etching, dry etching) and/or other suitable processes.

By completing step 111, the pad opening 53 is formed, and the semiconductor structure of the present disclosure is therefore obtained.

In some embodiments, sequential orders of performing steps 108, 109, 110 and 111 may be varied according to practical requirements, as long as that the first micro well 51, the second micro well 52, and the pad opening 53 having different heights and/or configuration are formed in different processes using different patterning masks 81, 82 and 83.

The embodiments of the present disclosure have the following advantageous features. The second micro well 52 formed with the second sensing layer 522 has a comparatively greater second height H2, which allows the second accommodation space 521 to have a comparatively greater second accommodation volume, so as to accommodate analyte in a greater volume and to increase contact surface between analyte and the second sensing layer 522, thereby enhancing intensity level of the signal to be detected. In addition, the first and second micro wells 51, 52 made with different heights are capable of producing signals with different intensity levels, allowing users to select processing and/or analysis of only one, or more than one signals.

In accordance with some embodiments of the present disclosure, a semiconductor structure includes a dielectric layer, a first stack and a second stack. The dielectric layer is formed on a base structure, and has an upper surface opposite to the base structure. The first stack includes a first routing, a first micro well and a first transistor. The first routing is formed in the dielectric layer, and has a first top portion and a first bottom portion opposite to the first top portion in a stacking direction. The first micro well extends downwardly from the upper surface of the dielectric layer into the first top portion, and has a first height. The first transistor is formed in the base structure and is connected to the first bottom portion. The second stack is displaced from the first stack in a direction transverse to the stacking direction, and includes a second routing, a second micro well, and a second transistor. The second routing is formed in the dielectric layer, and has a second top portion and a second bottom portion opposite to the second top portion in the stacking direction. The second micro well extends downwardly from the upper surface of the dielectric layer into the second top portion, and has a second height greater than the first height. The second transistor is formed in the base structure and is connected to the second bottom portion.

In accordance with some embodiments of the present disclosure, the first routing includes first metal layers, first vias, and a first gate contact. The first metal layers are connected to each other through the first vias. A topmost one of the first metal layers serves as the first top portion. The first gate contact serves as the first bottom portion. The second routing includes at least one second metal layer and a second gate contact. The at least one second metal layer serves as the second top portion. The second gate contact serves as the second bottom portion.

In accordance with some embodiments of the present disclosure, the at least one second metal layer includes a plurality of the second metal layers. The second routing further includes second vias. The second metal layers are connected to each other through the second vias. A topmost one of the plurality of second metal layers serves as the second top portion. A number of the first metal layers is larger than a number of the plurality of the second metal layers.

In accordance with some embodiments of the present disclosure, another one of the first metal layers, which is next to and below the topmost one of the first metal layers, is at a level same as a level of the topmost one of the plurality of the second metal layers.

In accordance with some embodiments of the present disclosure, each of the first metal layers and the plurality of the second metal layers includes an upper film, a lower film, and a main body sandwiched between the upper film and the lower film. Each of the upper film and the lower film includes a material different from a material of the main body.

In accordance with some embodiments of the present disclosure, the first micro well extends into the upper film to stop short of the main body of the topmost one of the first metal layers. The second micro well extends into the upper film to stop short of the main body of the topmost one of the plurality of the second metal layers.

In accordance with some embodiments of the present disclosure, the first stack further includes a first sensing layer disposed on an inner surface of the first micro well. The second stack further includes a second sensing layer disposed on an inner surface of the second micro well.

In accordance with some embodiments of the present disclosure, each of the first sensing layer and the second sensing layer includes an electrically conductive material, a dielectric material, a polymeric material, or combinations thereof.

In accordance with some embodiments of the present disclosure, a semiconductor structure includes a dielectric layer, a first stack and a second stack. The dielectric layer is formed on a base structure, and has an upper surface opposite to the base structure. The first stack includes a first routing, a first micro well and a first transistor. The first routing is formed in the dielectric layer, and has a first top portion and a first bottom portion opposite to the first top portion in a stacking direction. The first micro well extends downwardly from the upper surface of the dielectric layer into the first top portion, and has a first accommodation volume. The first transistor is formed in the base structure and is connected to the first bottom portion. The second stack is displaced from the first stack in a direction transverse to the stacking direction, and includes a second routing, a second micro well, and a second transistor. The second routing is formed in the dielectric layer, and has a second top portion and a second bottom portion opposite to the second top portion in the stacking direction. The second micro well extends downwardly from the upper surface of the dielectric layer into the second top portion. The second micro well has a second accommodation volume that is larger than the first accommodation volume. The second transistor is formed in the base structure and is connected to the second bottom portion.

In accordance with some embodiments of the present disclosure, the semiconductor structure further includes a pad stack displaced from the first stack and the second stack in the direction transverse to the stacking direction. The pad stack includes a third routing, a pad opening, and a third transistor. The third routing is formed in the dielectric layer, and has a third top portion and a third bottom portion opposite to the third top portion in the stacking direction. The pad opening extends downwardly from the upper surface of the dielectric layer into the third top portion. The third transistor is formed in the base structure and connected to the third bottom portion.

In accordance with some embodiments of the present disclosure, the first routing includes first metal layers, first vias, and a first gate contact. The first metal layers are connected to each other through the first vias. A topmost one of the first metal layers serves as the first top portion. The first gate contact serves as the first bottom portion. The second routing includes second metal layers, second vias and a second gate contact. The second metal layers are connected to each other through the second vias. A topmost one of the second metal layers serves as the second top portion. The second gate contact serves as the second bottom portion. The third routing includes third metal layers, third vias and a third gate contact. The third metal layers are connected to each other through the third vias. A topmost one of the third metal layers serves as the third top portion. The third gate contact serves as the third bottom portion. A number of the first metal layers is larger than a number of the second metal layers.

In accordance with some embodiments of the present disclosure, each of the first metal layers, the second metal layers and the third metal layers includes an upper film, a lower film, and a main body sandwiched between the upper film and the lower film. Each of the upper film and the lower film includes a material different from a material of the main body.

In accordance with some embodiments of the present disclosure, the pad opening penetrates through the upper film to stop at the main body of the topmost one of the third metal layers.

In accordance with some embodiments of the present disclosure, the second top portion is at a level lower than a level of the first top portion.

In accordance with some embodiments of the present disclosure, the first stack further includes a first sensing layer disposed on an inner surface of the first micro well so that the first sensing layer defines the first accommodation volume of the first micro well. The second stack further includes a second sensing layer disposed on an inner surface of the second micro well so that the second sensing layer defines the second accommodation volume of the second micro well.

In accordance with some embodiments of the present disclosure, a method for manufacturing a semiconductor structure includes: forming a first transistor and a second transistor in a base structure; forming a first dielectric portion over the base structure; forming a lower part of a first routing in the first dielectric portion, the lower part of the first routing including a first bottom portion which is connected to the first transistor; forming a second routing in the first dielectric portion, the second routing having a second top portion and a second bottom portion that is connected to the second transistor; forming a second dielectric portion over the first dielectric portion to cover the lower part of the first routing and the second routing; forming an upper part of the first routing in the second dielectric portion, the upper part of the first routing including a first top portion; forming a third dielectric portion over the second dielectric portion to cover the upper part of the first routing; forming a first micro well which extends from an upper surface of the third dielectric portion to expose the first top portion; and forming a second micro well which extends from the upper surface of the third dielectric portion through the second dielectric portion to expose the second top portion.

In accordance with some embodiments of the present disclosure, the method further includes: forming a first sensing layer on an inner surface of the first micro well; and forming a second sensing layer on an inner surface of the second micro well.

In accordance with some embodiments of the present disclosure, the method further includes: forming a third transistor in the base structure before forming the first dielectric portion; forming a lower part of a third routing in the first dielectric portion before forming the second dielectric portion, the lower part of the third routing including a third bottom portion which is connected to the third transistor; forming an upper part of the third routing in the second dielectric portion before forming the third dielectric portion, the upper part of the third routing including a third top portion; and forming a pad opening which extends from the upper surface of the third dielectric portion to expose the third top portion.

In accordance with some embodiments of the present disclosure, the first micro well, the second micro well and the pad opening are formed in different processes.

In accordance with some embodiments of the present disclosure, the first micro well, the second micro well and the pad opening are respectively formed using different patterning masks.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a dielectric layer formed on a base structure, and having an upper surface opposite to the base structure;
a first stack including:
a first routing formed in the dielectric layer, and having a first top portion and a first bottom portion opposite to the first top portion in a stacking direction,
a first micro well extending downwardly from the upper surface of the dielectric layer into the first top portion, the first micro well having a first height, and
a first transistor formed in the base structure and connected to the first bottom portion; and
a second stack displaced from the first stack in a direction transverse to the stacking direction, the second stack including:
a second routing formed in the dielectric layer, and having a second top portion and a second bottom portion opposite to the second top portion in the stacking direction,
a second micro well extending downwardly from the upper surface of the dielectric layer into the second top portion, the second micro well having a second height greater than the first height, and
a second transistor formed in the base structure and connected to the second bottom portion.

2. The semiconductor structure according to claim 1, wherein
the first routing includes first metal layers, first vias, and a first gate contact, the first metal layers being connected to each other through the first vias, a topmost one of the first metal layers serving as the first top portion, the first gate contact serving as the first bottom portion, and
the second routing includes at least one second metal layer and a second gate contact, the at least one second metal layer serving as the second top portion, the second gate contact serving as the second bottom portion.

3. The semiconductor structure according to claim 2, wherein:
the at least one second metal layer includes a plurality of the second metal layers, the second routing further including second vias, the second metal layers being connected to each other through the second vias, a topmost one of the plurality of second metal layers serving as the second top portion; and
a number of the first metal layers is larger than a number of the plurality of the second metal layers.

4. The semiconductor structure according to claim 3, wherein another one of the first metal layers, which is next to and below the topmost one of the first metal layers, is at a level same as a level of the topmost one of the plurality of the second metal layers.

5. The semiconductor structure according to claim 3, wherein each of the first metal layers and the plurality of the second metal layers includes an upper film, a lower film, and a main body sandwiched between the upper film and the lower film, each of the upper film and the lower film including a material different from a material of the main body.

6. The semiconductor structure according to claim 5, wherein the first micro well extends into the upper film to stop short of the main body of the topmost one of the first metal layers, and the second micro well extends into the upper film to stop short of the main body of the topmost one of the plurality of the second metal layers.

7. The semiconductor structure according to claim 1, wherein:
the first stack further includes a first sensing layer disposed on an inner surface of the first micro well; and
the second stack further includes a second sensing layer disposed on an inner surface of the second micro well.

8. The semiconductor structure according to claim 7, wherein each of the first sensing layer and the second sensing layer includes an electrically conductive material, a dielectric material, a polymeric material, or combinations thereof.

9. A semiconductor structure, comprising:
a dielectric layer formed on a base structure, and having an upper surface opposite to the base structure;
a first stack including:
a first routing formed in the dielectric layer, and having a first top portion and a first bottom portion opposite to the first top portion in a stacking direction,
a first micro well extending downwardly from the upper surface of the dielectric layer into the first top portion, the first micro well having a first accommodation volume, and
a first transistor formed in the base structure and connected to the first bottom portion; and
a second stack displaced from the first stack in a direction transverse to the stacking direction, the second stack including:
a second routing formed in the dielectric layer, and having a second top portion and a second bottom portion opposite to the second top portion in the stacking direction,
a second micro well extending downwardly from the upper surface of the dielectric layer into the second top portion, the second micro well having a second accommodation volume that is larger than the first accommodation volume, and
a second transistor formed in the base structure and connected to the second bottom portion.

10. The semiconductor structure according to claim 9, further comprising a pad stack displaced from the first stack and the second stack in the direction transverse to the stacking direction, the pad stack including:
a third routing formed in the dielectric layer, and having a third top portion and a third bottom portion opposite to the third top portion in the stacking direction,
a pad opening extending downwardly from the upper surface of the dielectric layer into the third top portion, and
a third transistor formed in the base structure and connected to the third bottom portion.

11. The semiconductor structure according to claim 10, wherein:
the first routing includes first metal layers, first vias, and a first gate contact, the first metal layers being connected to each other through the first vias, a topmost one of the first metal layers serving as the first top portion, the first gate contact serving as the first bottom portion;
the second routing includes second metal layers, second vias and a second gate contact, the second metal layers being connected to each other through the second vias, a topmost one of the second metal layers serving as the second top portion, the second gate contact serving as the second bottom portion;
the third routing includes third metal layers, third vias and a third gate contact, the third metal layers being connected to each other through the third vias, a topmost one of the third metal layers serving as the third top portion, the third gate contact serving as the third bottom portion; and
a number of the first metal layers is larger than a number of the second metal layers.

12. The semiconductor structure according to claim 11, wherein each of the first metal layers, the second metal layers and the third metal layers includes an upper film, a lower film, and a main body sandwiched between the upper film and the lower film, each of the upper film and the lower film including a material different from a material of the main body.

13. The semiconductor structure according to claim 12, wherein the pad opening penetrates through the upper film to stop at the main body of the topmost one of the third metal layers.

14. The semiconductor structure according to claim 9, wherein the second top portion is at a level lower than a level of the first top portion.

15. The semiconductor structure according to claim 9, wherein:
the first stack further includes a first sensing layer disposed on an inner surface of the first micro well so that the first sensing layer defines the first accommodation volume of the first micro well; and
the second stack further includes a second sensing layer disposed on an inner surface of the second micro well so that the second sensing layer defines the second accommodation volume of the second micro well.

16. A method for manufacturing a semiconductor structure, comprising:
forming a first transistor and a second transistor in a base structure;
forming a first dielectric portion over the base structure;
forming a lower part of a first routing in the first dielectric portion, the lower part of the first routing including a first bottom portion which is connected to the first transistor;
forming a second routing in the first dielectric portion, the second routing having a second top portion and a second bottom portion that is connected to the second transistor;
forming a second dielectric portion over the first dielectric portion to cover the lower part of the first routing and the second routing;
forming an upper part of the first routing in the second dielectric portion, the upper part of the first routing including a first top portion;
forming a third dielectric portion over the second dielectric portion to cover the upper part of the first routing;
forming a first micro well which extends from an upper surface of the third dielectric portion to expose the first top portion; and
forming a second micro well which extends from the upper surface of the third dielectric portion through the second dielectric portion to expose the second top portion.

17. The method according to claim 16, further comprising:
forming a first sensing layer on an inner surface of the first micro well; and
forming a second sensing layer on an inner surface of the second micro well.

18. The method according to claim 16, further comprising:
forming a third transistor in the base structure before forming the first dielectric portion;
forming a lower part of a third routing in the first dielectric portion before forming the second dielectric portion, the lower part of the third routing including a third bottom portion which is connected to the third transistor;
forming an upper part of the third routing in the second dielectric portion before forming the third dielectric portion, the upper part of the third routing including a third top portion; and
forming a pad opening which extends from the upper surface of the third dielectric portion to expose the third top portion.

19. The method according to claim 18, wherein the first micro well, the second micro well and the pad opening are formed in different processes.

20. The method according to claim 18, wherein the first micro well, the second micro well and the pad opening are respectively formed using different patterning masks.
